(19) United States
(12) Patent Application Publication
(10) Pub. No.: US 2004/0252848 A1
(43) Pub. Date: Dec. 16, 2004

(54) METHOD OF PROCESSING SOUND SIGNAL USING A COMMUNICATION DEVICE

(76) Inventor: Wen-Way Chen, Ping-Tung Hsien (TW)

Correspondence Address: NAIPO (NORTH AMERICA INTERNATIONAL PATENT OFFICE), P.O. BOX 506, MERRIFIELD, VA, 22116, US

(21) Appl. No.: 10/709,567

(22) Filed: May 14, 2004

(30) Foreign Application Priority Data
Jun. 12, 2003 (TW) 092116015

(51) Int. Cl. H03G 3/00; H04B 3/00

(52) U.S. Cl. 381/77; 381/104; 381/107

(57) ABSTRACT

A method of processing sound signals in a communication device is disclosed. The communication device comprises a sound receiving unit, a storage unit, an processing unit, and a transceiving unit, the method comprises;(a) receiving a first sound signal by using the sound receiving unit; (b) processing the first sound signal and a second sound signal stored in the storage unit by using the processing unit; and (c) sending the processed first sound signal and the processed second sound signal to the transceiving unit, so that a listener is capable of simultaneously listening to the processed first sound signal and the processed second sound signal.

### BACKGROUND OF INVENTION

1. Field of the Invention

The present invention relates to a communication device, and more specifically, to a communication device capable of processing sound signals.

2. Description of the Prior Art

Owing to the rapid development of wireless communication systems, a handy communication device of great convenience is widely used in daily communications. With convenient communication devices, people are able to exchange information, share experiences, and communicate with each other anytime and anywhere.

Due to the portability of communication devices, people are capable of transmitting sound signals and exchanging opinions by using communication devices. The ambient sound of the speaker can also be received by a sound receiving unit (i.e. a microphone), which could enable the listener to guess the location of the speaker. However, if the speaker is in an environment filled with unnecessary noises, the communication contents filled with irrelevant sounds from the noisy environment probably make communication uncomfortable. Using conventional communication devices for receiving and processing sound signals, may not be what the speaker desires. The speaker might wish to filter off ambient sounds, so that the possible location of the speaker is not given away.

Please refer to FIG. 1, which shows a block diagram of a communication device 10 used for processing sound signals according to the prior art. The communication device 10 comprises a sound receiving unit 12, an analog-to-digital converter (ADC) 14, a transceiving unit 16, and a sound-outputting unit 18. The sound receiving unit 12, electrically connected with the ADC 14, is used for receiving sound signals from a speaker. The ADC 14, electrically connected between the sound receiving unit 12 and the transceiving unit 16, is used for transforming analog sound signals received by the sound receiving unit 12 into digital sound signals. The transceiving unit 16, electrically connected to the sound receiving unit 12, is used for transceiving radio signals. The sound-outputting unit 18 is used for outputting digital sound signals. The conventional communication device 10 receives sound signals by using the sound receiving unit 12 and then transforms analog sound signals into digital signals by using the ADC 14. After the communication device 10 establishes a connection with the listening end, the transformed digital sound signals are sent to the transceiving unit 16 and then broadcasted to the listening end. The sound signals and the ambient noise are completely received by the sound-outputting unit 18, processed by the ADC 14, and then sent to the transceiving unit 16 for broadcasting to the listening end. In other words, the sound signal from the speaker using the conventional communication device 10 and the ambient noise are all transceived by the transceiving unit 16 and sent to the listening end, so that the speaker is not able to control and select the content of the sound.

As mentioned, the conventional communication device 10 lacks a mechanism for selecting and controlling desired sound signals. As far as a user, who desires to individualize sound signals or requires concealing communication environments to maintain personal privacy, is concerned, the conventional communication device 10 cannot satisfy the users demand.

In short, relevant industries have focused on developing individualized communication products in the third generation mobile communication techniques. The conventional mobile communication lacks suitable techniques for concealing the location of a user. Under very extreme circumstances this may threaten the life and possessions of the user.

### SUMMARY OF INVENTION

It is therefore a primary objective of the claimed invention to provide a method for processing sound signals used in a communication device, to solve the aforementioned problem.

According to the claimed invention, a method of processing sound signals in a communication device is disclosed. The communication device comprises a sound receiving unit, a storage unit, a processing unit, and a transceiving unit. The method comprises:(a) receiving a first sound signal by using the sound receiving unit; (b) processing the first sound signal and a second sound signal stored in a storage unit by using the processing unit; and (c) sending the processed first sound signal and the processed second sound signal to the transceiving unit, so that a listener is capable to simultaneously listen to the processed first sound signal and the processed second sound signal.

These and other objects and the advantages of the present invention will no doubt become obvious to those of ordinary skill in the art after having read the following detailed description of the preferred embodiment, as illustrated by the included figures and drawings.

### BRIEF DESCRIPTION OF DRAWINGS

FIG. 1 is a block diagram of a communication device used for processing sound signals according to the prior art.

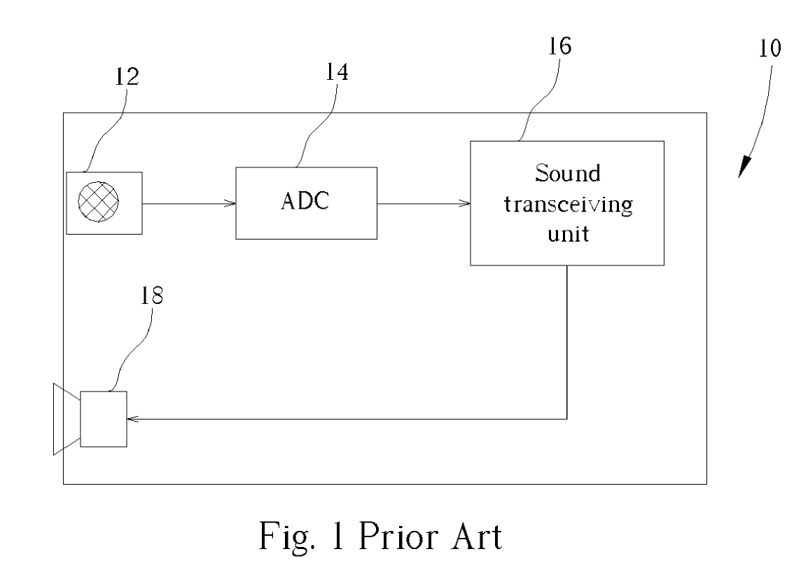

FIG. 2 is a block diagram of the communication device according to the present invention.

FIG. 3 is a block diagram of another embodiment of the communication device according to the present invention.

FIG. 4 is a flowchart of processing sound signals using the communication according to the present invention.

### DETAILED DESCRIPTION

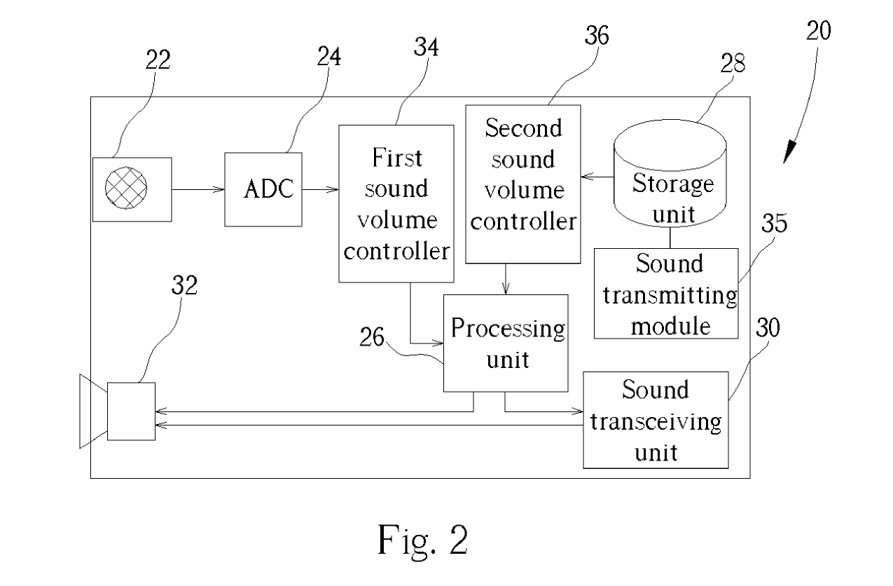

Please refer to FIG. 2, which shows a block diagram of the communication device 20 according to the present invention. The communication device 20 comprises a sound receiving unit 22 (e.g. a microphone) for receiving a first sound signal from a user, an analog-to-digital converter (ADC) 24, an processing unit 26, a storage unit 28 (e.g. a memory) for storing sound files recorded by the user or set by the communication device 20, serving as a second sound signal, a transceiving unit (e.g. a transceiver) 30, a sound-outputting unit 32 (e.g. an amplifier), a first sound volume controller 34, and a second sound volume controller 36. The communication device 20 further comprises a sound transmitting module 35capable of inputting sound from an external sound source and storing the sound into the storage unit 28 through a cable. The processing unit 26 receives the first sound signal from the ADC 24 and the second sound signal stored in the storage unit 28, mixes the two sound signals into a third sound signal, and then delivers the third sound signal to the transceiving unit 30 or the sound-outputting unit 32. The transceiving unit 30, electrically connected to the processing unit 26, is used for outputting the third sound signal to a receiving terminal, of which a listener is also capable of listening to the first sound signal and the second sound signal. The sound-outputting unit 32 is electrically connected with the processing unit and the transceiving unit 30 is used for outputting the third sound signal and sound received by the transceiving unit 30. The first sound volume controller 34, electrically connected between the ADC 24 and the processing unit 26, is used for adjusting the magnitude of the first sound signal from the sound receiving unit 22. The second sound volume controller 36, electrically connected between the storage unit 28 and the processing unit 26, is used for storing the volume of the second sound signal stored in the storage unit 28.

In order to facilitate the use, the communication device 20 also contains a control interface (not shown in FIG. 2) for receiving control signals inputted by the user, to adjust the first sound volume controller 34 and the second sound volume controller 36, and to provide alternatives for performing the sound files stored in the storage unit 28. By means of using the control interface, after hearing the third sound signal through the sound-outputting unit 32, which combines the first sound signal from the sound receiving unit 22 with the second sound signal in the sound files stored in the storage unit 28 using the first processing unit 26, the user decides whether to adopt related settings for the third sound signal.

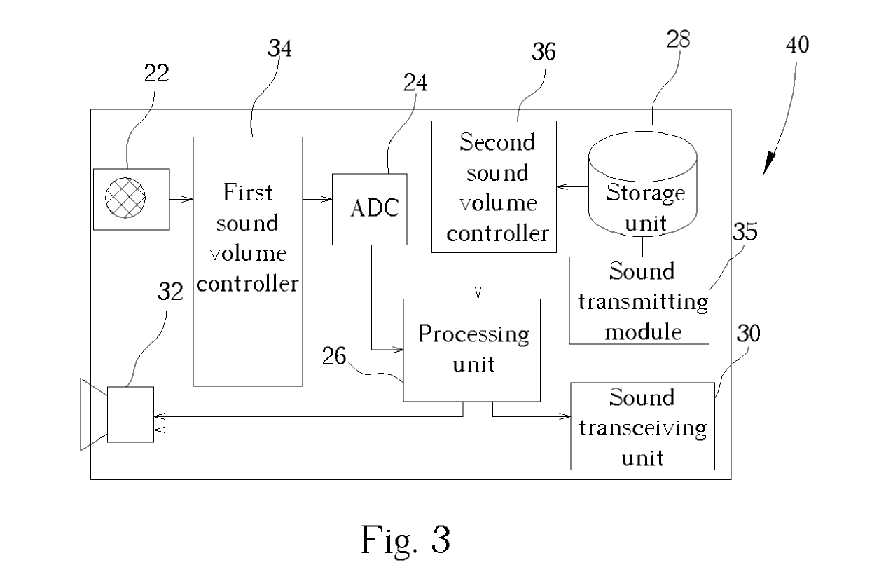

Please refer to FIG. 3, which is a block diagram of another embodiment of the communication device 40 according to the present invention. Differing from the communication device 20, the ADC 24 of the communication device 40 shown in FIG. 3 is electrically connected between the first sound volume controller 34 and the processing unit 26, which is also used for transforming an analog sound signal from the sound receiving unit 22 into a digital sound signal.

Moreover, within the first embodiment communication device 20 or the second embodiment communication device 40, the ADC 24, the first sound volume controller 34, the second sound volume controller 36, and the processing unit 26 are capable of being integrated into a single processing element for the same implementations.

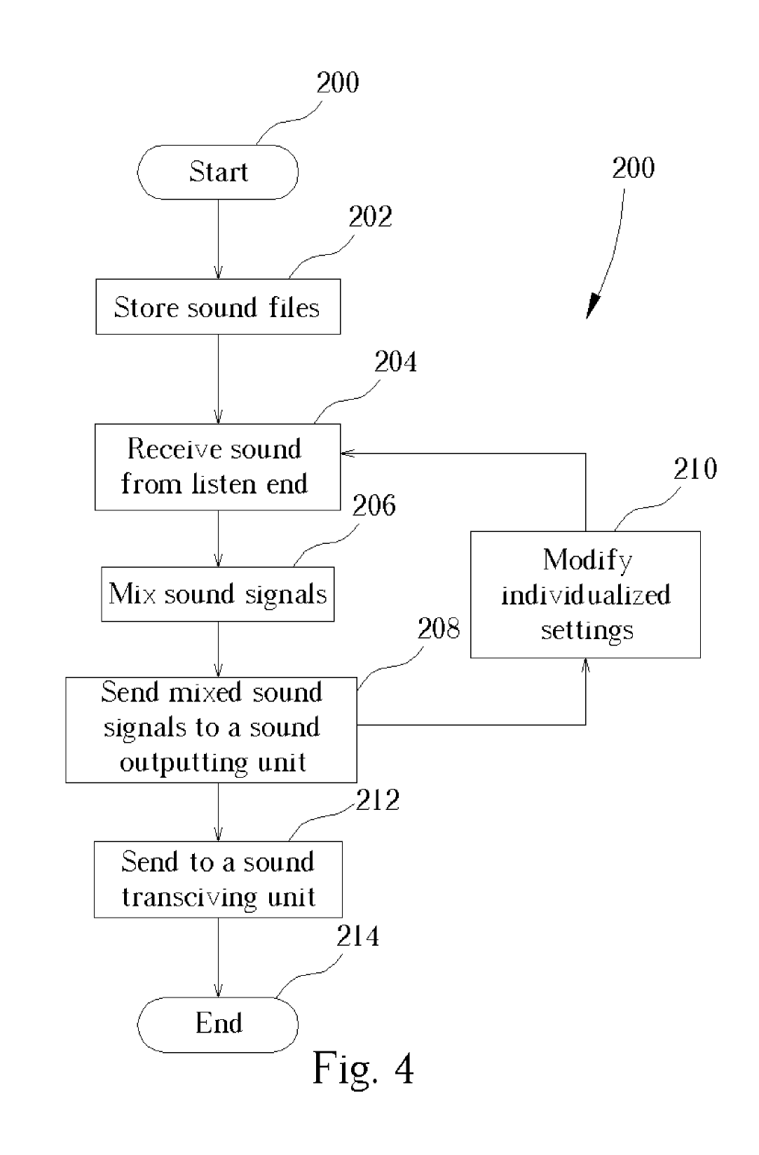

Please refer to FIG. 4, which is a flowchart of processing sound signals using the communication device 20according to the present invention. It occurs as follows:

Step 200: Start.

Step 202: Store the sound files. The storage unit 28 of the communication device 20,used for storing sound files, having a plurality of predefined sound signals. Furthermore, the sound file could be any sound, which is recorded by the sound receiving unit 22, transformed into the digital sound with the ADC 24, and then stored in the storage unit 28, depending on the user's desire. The sound file also can be recorded from other external sound sources and directly stored into the storage unit 28. It is clear that the way of inputting sound signals is not an essential implementation element of the present invention. Any similar way for inputting the sound signals is not regarded as a limitation for the present invention.

Step 204:Receive the sound signal from the speaker. When the speaker wants to individualize self-sound signals and ambient sounds, actuate the sound receiving unit 22 of the communication device 20 and speak to the sound receiving unit 22 to generate the analog self-sound signal. By using the ADC 24, the analog self-sound signal is transformed into a digital sound signal. After that, the digital sound signal is transmitted to the processing unit 26. Go to step 206.

Step 206:Mix sound signals. The processing unit 26 is a processor, which is capable of performing associated program code. The processing unit 26 mixes the sound signal of the speaker from the ADC 24, and one or more sound signals selected from the sound files in the storage unit 28, to form a new sound signal. The new highly correlated sound signal is very hard to distinguish. By utilizing the processing unit 26, any desired sound signal of the sound file can be chosen and is combined with the sound signal of the user into the new sound signal.

Step 208:Transmit the mixed sound signal to the sound-outputting unit 32. The mixed sound signal is transmitted to the sound-outputting unit 32 and broadcasts it to the user. If the user identifies the mixed sound signal, go to step 212; if not, go to step 210 for doing further modification.

Step 210:Modify individualized settings. The communication device 20 comprises a control interface used to receive a control signal from the user to adjust the first sound volume controller 34 and the second sound volume controller 36 for the sound volume control. The control interface also provides alternatives to operate the sound file in the storage unit 28. With the control interface, the user is able to adjust the first and the second sound volume controllers 34, 36 for modifying a sound magnitude of the sound signals from the sound receiving unit 32 and from the sound file in the storage unit 28 if dissatisfied with the result of step 208. The user is also able to select other sound signals again from the plurality of sound files in the storage unit 28.

Step 212: Transmit to the transceiving unit 30. After the previous settings for the sound signal, the mixed sound signals are transmitted to the transceiving unit 30, so that the user is able to communicate with others using the mixed sound signals.

Step 214: End.

The key point of the present invention is to provide the storage unit 28, the processing unit 26, and the control interface. The user is capable of picking up the sound signal freely from the storage unit 28 in which the sound signals is pre-recorded or predefined by the user. In addition, the user is able to adjust the self-sound magnitude, or the sound signal in the sound file through the control interface. Moreover, by means of the processing unit 26, the mixed sound signal, the self-sound signal and the selected sound signal are capable of combining a natural sound signal. To do so, by using the present method of processing the sound signal, the user is capable of creating the individualized sound signal, which the conventional communication device fails to realize. Even under different communicating circumstances, the user is also able to select a sound signal from a specific sound file, and adjust the sound magnitude of the selected sound signal, that of the user sound signal, in order to prevent leaking out the user's location by creating individualized sound signals. For instance, once the user chooses a sound signal similar to the sound of engines, the present invention is able to combine the sound signal the user picks with the sound of engines, in order to form a natural sound. As a result, a tranquil environment is concealed because the listener would listen to the speaker's voice while hearing a noisy engine sound in the background.

For the user who wants to individualize the sound signal or conceal the ambient sound to keep the users privacy, the ambient sound signal is capable of correctly receiving conventional sound by using processing techniques. However, it is lacking alternatives of sound signals for the user. Compared to the prior art, the user is able to exchange information, share experiences, and communicate with others while keeping his privacy by using the present invention communication device. As a result, using the present invention communication device, more security is provided for the personal digital mobile information products.

Notice that the present invention communication device could be a mobile phone or other similar communication implementations.

Those skilled in the art will readily observe that numerous modifications and alterations of the device may be made while retaining the spirit and scope of the invention. Accordingly, the above disclosure should be construed as limited only by the metes and bounds of the appended claims.

What is claimed is:

1. A method of processing sound signals in a communication device, the communication device comprising a sound receiving unit, a storage unit, an processing unit, and a transceiving unit, the method comprising:
(a)receiving a first sound signal by using the sound receiving unit;
(b)processing the first sound signal and a second sound signal stored in the storage unit by using the processing unit; and
(c)sending the processed first sound signal and the processed second sound signal to the transceiving unit, so that a listener is capable of simultaneously listening the processed first sound signal and the processed second sound signal.

2. The method of claim 1, wherein the communication device comprises a first sound volume controller, electrically connected with the sound receiving unit and the processing unit, the method further comprising adjusting magnitude of the first sound signal by using the first sound volume controller before performing step (b).

3. The method of claim 1, wherein the sound receiving unit is a microphone.

4. The method of claim 1, wherein the communication device comprises a second sound volume controller, electrically connected between the storage unit and the processing unit, the method further comprising adjusting magnitude of the second sound signal by using the second sound volume controller before performing the step (b).

5. The method of claim 2, wherein the communication device comprises an analog-to-digital converter, electrically connected between the storage unit and the first sound volume controller, for transforming an analog sound signal into a digital sound signal.

6. The method of claim 2, wherein the communication device comprises an analog-to-digital converter, electrically connected between the processing unit and the first sound volume controller, for transforming an analog sound signal into a digital sound signal.

7. The method of claim 1, wherein the communication device further comprises a sound-outputting unit, electrically connected to the processing unit, the method further comprising outputting the processed first sound signal and the processed second sound signal to the sound-outputting unit.

8. The method of claim 7, wherein the sound-outputting unit is an amplifier.

9. A communication device for performing the method of claim 1.

10. A communication device comprising:
a sound receiving unit for receiving a first sound signal;
a storage unit for storing at least a second sound signal;
an processing unit, electrically connected to/between the sound receiving unit and the storage unit, for processing the first sound signal and the second sound signal; and
a transceiving unit, electrically connected to the processing unit, for outputting the processed first sound signal and the processed second sound signal.

11. The communication device of claim 10, further comprising a first sound volume controller, electrically connected with the sound receiving unit and the processing unit, for adjusting magnitude of the first sound signal.

12. The communication device of claim 11, further comprising an analog-to-digital converter, electrically connected between the storage unit and the first sound volume controller, for transforming an analog sound signal into a digital sound signal.

13. The communication device of claim 11, further comprising an analog-to-digital converter, electrically connected between the processing unit and the first sound volume controller, for transforming an analog sound signal into a digital sound signal.

14. The communication device of claim 10, further comprising a second sound volume controller, electrically connected with the storage unit and the processing unit, for adjusting magnitude of the second sound signal.

15. The communication device of claim 10, further comprising a sound-outputting unit for outputting the processed first sound signal and the processed second sound signal.

16. The communication device of claim 15, wherein the sound-outputting unit is an amplifier.

17. The communication device of claim 10, further comprising a control interface for inputting a control signal.

18. The communication device of claim 10, wherein the sound receiving unit is a microphone.
